(19) United States
(12) Patent Application Publication
(10) Pub. No.: US 2011/0290316 A1
(43) Pub. Date: Dec. 1, 2011

(54) LIGHT SCATTERING INORGANIC SUBSTRATES BY SOOT DEPOSITION

(76) Inventors: Daniel Warren Hawtof, Corning, NY (US); Glenn Eric Kohnke, Corning, NY (US); Jia Liu, Painted Post, NY (US)

(21) Appl. No.: 13/110,188

(22) Filed: May 18, 2011

Related U.S. Application Data
(60) Provisional application No. 61/349,392, filed on May 28, 2010.

(51) Int. Cl. H01L 31/0236; G02B 5/02; B05D 5/12

(52) U.S. Cl. 136/256; 427/74; 359/599

(57) ABSTRACT

Light scattering inorganic substrates and articles comprising soot particles and methods for making light scattering inorganic substrates and articles comprising soot particles useful for, for example, photovoltaic cells. The method for making the substrates and articles comprises providing an inorganic substrate comprising at least one surface, applying soot particles pyrogenically to the at least one surface of the inorganic substrate to form a coated substrate, and heating the soot particles to form the light scattering inorganic substrate. The invention creates a scattering glass surface that is suitable for subsequent deposition of a TCO and a thin film silicon photovoltaic device structure. The scattering properties may be controlled by the combination of substrate glass and soot composition, deposition conditions, patterning of the soot, and/or sintering conditions.

This application claims the benefit of priority under 35 U.S.C. §119 of U.S. Provisional Application Ser. No. 61/349,392 filed on May 28, 2010 the content of which is relied upon and incorporated herein by reference in its entirety.

### BACKGROUND

1. Field

Embodiments relate generally to light scattering inorganic substrates and methods for making light scattering inorganic substrates, and more particularly to light scattering inorganic substrates comprising soot particles and methods for making light scattering inorganic substrates comprising soot particles useful for, for example, photovoltaic cells.

2. Technical Background

For thin-film silicon photovoltaic solar cells, light must be effectively coupled into the silicon layer and subsequently trapped in the layer to provide sufficient path length for light absorption. A path length greater than the thickness of the silicon is especially advantageous at longer wavelengths where the silicon absorption length is typically tens to hundreds of microns. A typical tandem cell incorporating both amorphous and microcrystalline silicon typically has a substrate having a transparent electrode deposited thereon, a top cell of amorphous silicon, a bottom cell of microcrystalline silicon, and a back contact or counter electrode. Light is typically incident from the side of the deposition substrate such that the substrate becomes a superstrate in the cell configuration.

Amorphous silicon absorbs primarily in the visible portion of the spectrum below 700 nanometers (nm) while microcrystalline silicon absorbs similarly to bulk crystalline silicon with a gradual reduction in absorption extending to ˜1200 nm. Both types of material benefit from textured surfaces. Depending on the size scale of the texture, the texture performs light trapping and/or reduces Fresnel loss at the Si/substrate interface.

The transparent electrode (also known as transparent conductive oxide, TCO) is typically a film of fluorine doped-SnO₂ or boron or aluminum doped-ZnO with a thickness on the order of 1 micron that is textured to scatter light into the amorphous Si and the microcrystalline Si. The primary measure of scattering is called “haze” and is defined as the ratio of light that is scattered >2.5 degrees out of a beam of light going into a sample and the total light transmitted through the sample. The scattering distribution function is not captured by this single parameter and large angle scattering is more beneficial for enhanced path length in the silicon compared with narrow angle scattering. Additional work on different types of scattering functions indicate that improved large angle scattering has a significant impact on cell performance.

The TCO surface is textured by various techniques. For SnO₂, the texture is controlled by the parameters of the chemical vapor deposition (CVD) process used to deposit the films. An example of a textured SnO₂ film is, for example, Asahi-U films produced by Asahi Glass Company. For ZnO, the texture is controlled by the deposition parameters for CVD deposited films or plasma treatment or wet etching is used to create the desired morphology after deposition for sputtered films.

Disadvantages with textured TCO technology can include one or more of the following: 1) texture roughness degrades the quality of the deposited silicon and creates electrical shorts such that the overall performance of the solar cell is degraded; 2) texture optimization is limited both by the textures available from the deposition or etching process and the decrease in transmission associated with a thicker TCO layer; and 3) plasma treatment or wet etching to create texture adds cost in the case of ZnO.

Another approach to the light-trapping needs for thin film silicon solar cells is texturing of the substrate beneath the TCO and/or the silicon deposition, rather than texture a deposited film. In some conventional thin film silicon solar cells, vias are used instead of a TCO to make contacts at the bottom of the Si that is in contact with the substrate. The texturing in some conventional thin film silicon solar cells consist of SiO₂ particles in a binder matrix deposited on a planar glass substrate. This type of texturing is typically done using a sol-gel type process where the particles are suspended in liquid, the substrate is drawn through the liquid, and subsequently sintered. The beads remain spherical in shape and are held in place by the sintered gel.

Many additional methods have been explored for creating a textured surface prior to TCO deposition. These methods include sandblasting, polystyrene microsphere deposition and etching, and chemical etching. These methods related to textured surfaces can be limited in terms of the types of surface textures that can be created.

Light trapping is also beneficial for bulk crystalline Si solar cells having a Si thickness less than about 100 microns. At this thickness, there is insufficient thickness to effectively absorb all the solar radiation in a single or double pass (with a reflecting back contact). Therefore, cover glasses with large scale geometric structures have been developed to enhance the light trapping. For example, an EVA (ethyl-vinyl acetate) encapsulant material is located between the cover glass and the silicon. Examples of such cover glasses are the Albarino® family of products from Saint-Gobain Glass. A rolling process is typically used to form this large-scale structure.

Disadvantages with the textured glass superstrate approach can include one or more of the following: 1) sol-gel chemistry and associated processing is required to provide binding of glass microspheres to the substrate; 2) the process creates textured surfaces on both sides of the glass substrate; 3) additional costs associated with silica microspheres and sol-gel materials; and 4) problems of film adhesion and/or creation of cracks in the silicon film.

It would be advantageous to have a method for making a light scattering inorganic substrate wherein the process is scalable to larger substrates and wherein the surface can be tailored to produce desired light scattering.

### SUMMARY

Methods for making a light scattering inorganic substrate, as described herein, address one or more of the above-mentioned disadvantages of conventional methods and may provide one or more of the following advantages: the glass microstructure coated with TCO may be smoothly varying and less likely to create electrical problems, the glass texture may be optimized without concern of an absorption penalty unlike in the case of a textured TCO more texture requires regions of thicker TCO resulting in higher absorption, the process does not require a binder that can be sintered as in the case of sol-gel processes, and the texture feature size may be controlled with the sintering process.

One embodiment is a method for making a light scattering inorganic substrate. The method comprises providing an inorganic substrate comprising at least one surface, applying soot particles pyrogenically to the at least one surface of the inorganic substrate to form a coated substrate, and heating the coated substrate to form the light scattering inorganic substrate.

Another embodiment is a light scattering article comprising a glass substrate having a surface comprising a pattern of textured areas comprising glass soot and a pattern of non-textured areas.

Photovoltaic devices such as thin film photovoltaic devices such as silicon tandem photovoltaic devices can comprise the light scattering articles.

Additional features and advantages of the invention will be set forth in the detailed description which follows, and in part will be readily apparent to those skilled in the art from the description or recognized by practicing the invention as described in the written description and claims hereof, as well as the appended drawings.

It is to be understood that both the foregoing general description and the following detailed description are merely exemplary of the invention, and are intended to provide an overview or framework for understanding the nature and character of the invention as it is claimed.

The accompanying drawings are included to provide a further understanding of the invention, and are incorporated in and constitute a part of this specification. The drawings illustrate one or more embodiment(s) of the invention and together with the description serve to explain the principles and operation of the invention.

### BRIEF DESCRIPTION OF THE DRAWINGS

The invention can be understood from the following detailed description either alone or together with the accompanying drawing figures.

FIG. 1 is an illustration of an exemplary soot particle deposition apparatus.

FIG. 2 is a cosine-corrected bidirectional transmittance function (ccBTDF) at 400 nm, 600 nm, 800 nm, and 1000 nm of exemplary light scattering inorganic substrates made according to some embodiments.

FIGS. 3A and 3B are scanning electron microscope (SEM) images of exemplary light scattering inorganic substrates made according to some embodiments.

FIGS. 4A and 4B are scanning electron microscope (SEM) images of exemplary light scattering inorganic substrates made according to some embodiments.

FIGS. 5A and 5B are scanning electron microscope (SEM) images of exemplary light scattering inorganic substrates made according to some embodiments.

FIGS. 6A-6C are illustrations of exemplary light scattering articles having patterned soot.

FIG. 7 is an illustration of features of an exemplary photovoltaic device using light scattering substrates or articles according to the invention.

### DETAILED DESCRIPTION

Reference will now be made in detail to various embodiments of the invention, examples of which are illustrated in the accompanying drawings. Wherever possible, the same reference numbers will be used throughout the drawings to refer to the same or like parts.

As used herein, the term “substrate” can be used to describe either a substrate or a superstrate depending on the configuration of the photovoltaic cell. For example, the substrate is a superstrate, if when assembled into a photovoltaic cell, it is on the light incident side of a photovoltaic cell. The superstrate can provide protection for the photovoltaic materials from impact and environmental degradation while allowing transmission of the appropriate wavelengths of the solar spectrum. Further, multiple photovoltaic cells can be arranged into a photovoltaic module.

As used herein, the term “adjacent” can be defined as being in close proximity. Adjacent structures may or may not be in physical contact with each other. Adjacent structures can have other layers and/or structures disposed between them.

One embodiment is a method for making a light scattering inorganic substrate. The method comprises providing an inorganic substrate comprising at least one surface, applying soot particles pyrogenically to the at least one surface of the inorganic substrate to form a coated substrate, and heating the coated substrate to form the light scattering inorganic substrate.

Another embodiment is a light scattering article comprising a glass substrate having a surface comprising a pattern of textured areas comprising glass soot and a pattern of non-textured areas.

Photovoltaic devices such as thin film photovoltaic devices such as silicon tandem photovoltaic devices can comprise the light scattering articles.

A pyrogenic method can be, for example, a chemical vapor deposition method such as outside vapor deposition, flame hydrolysis, plasma or plasma assisted deposition, or flame spray pyrolysis. A pyrogenic process can be used, for example, with a burner as is used for depositing soot for the fabrication of optical fibers by outside-vapor deposition (OVD). Silica and doped silica particles can be pyrogenically generated in a flame and deposited as soot particles. For example, the soot deposition process may employ one or more passes of silica or doped silica soot layers. Silica and/or other oxide containing vapors may be provided to the OVD burner by a reactant delivery system to thereby deposit the silica or other oxide soot. Silica soot particles may be formed from an outside vapor deposition (OVD) process in which silica glass is deposited on an inorganic substrate, for example, through the hydrolysis of octamethylcyclotetrasiloxane (OMCTS).

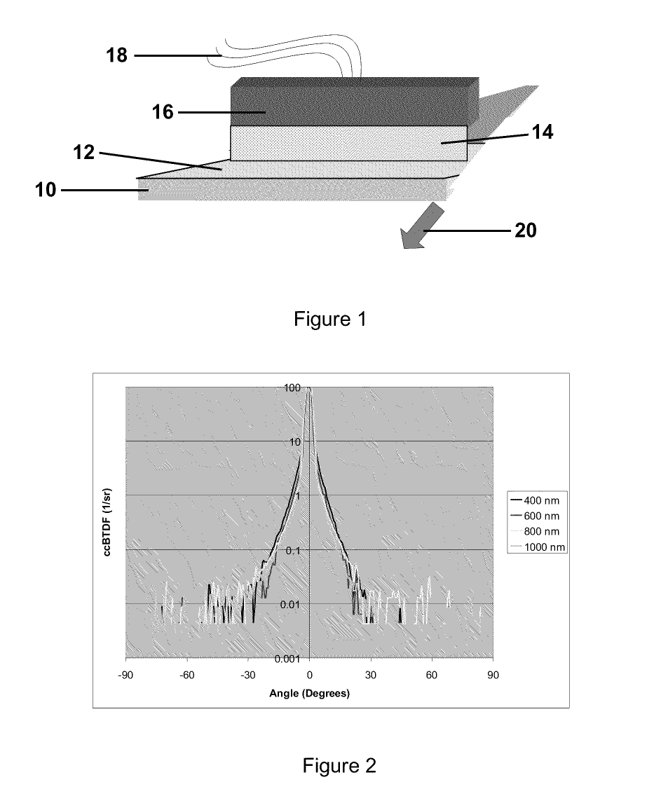

According to one embodiment, the application of the soot particles comprises depositing the soot particles using a linear burner, a point source burner, a series of linear burners, a series of point source burners, an array of linear burners, or an array of point source burners. A deposition system comprising a linear burner is shown in FIG. 1. The substrate can be translated under any one of the above mentioned burners or any one of the above mentioned burners can be translated across the surface of the substrate to deposit the particles. A series or an array of burners can be placed side by side or one in front of the other. These burner configurations can be used to deposit different compositions or different sized particles.

The coated substrate comprises the soot particles deposited on the inorganic substrate. In one embodiment, heating the coated substrate comprises sintering the deposited soot particles. In this embodiment, low softening temperature soot particles can be deposited on a high softening temperature substrate. The soot particles can be partially sintered wherein some individual soot particles are visible, or fully sintered such that the particles flow to form a homogenous layer. The particles also attach to the substrate during the sintering process.

In one embodiment, heating the coated substrate comprises softening the inorganic substrate. In this embodiment, high softening temperature soot particles can be deposited on a low softening temperature substrate. The substrate can be softened such that the surface with the deposited soot particles deforms and the particles do not soften. The softened surface can partially engulf a portion of or all of the particles. The particles also attach to the substrate during the heating process.

In one embodiment, heating the coated substrate comprises softening the inorganic substrate and sintering the soot particles. In this embodiment, the softening temperatures of the soot particles and the substrate are the same. The soot particles can be partially sintered wherein some individual soot particles are visible, or fully sintered such that the particles flow to form a homogenous layer. The substrate can be softened such that the surface with the deposited soot particles deforms and the particles also soften. The softened surface can partially engulf a portion of or all of the softened particles. A portion of the substrate, such as the surface, may flow along with the particles to form a light scattering substrate. The particles also attach to the substrate during the heating process.

The heating or the sintering temperature can be adjusted depending on the softening temperatures of either the substrate, the soot particles, or both. Depending on the combination of materials for the soot particles and the substrate and the sintering temperature, either the soot particles, substrate, or both can be sintered. According to some embodiments, the sintering temperature is in the range of from 500° C. to 1600° C.

The inorganic substrate, in one embodiment, comprises a material selected from a glass, a ceramic, a glass ceramic, sapphire, silicon carbide, a semiconductor, and combinations thereof.

In one embodiment, applying the soot particles comprises patterning the soot particles.

In one embodiment, the method further comprises patterning the soot particles after applying.

The location of the texture, area having soot particles, on the substrate may be controlled by patterning the soot prior to sintering. This may be done on a macro scale by, for example, leaving a specified area of non-textured glass around the edge of the substrate. It may also be done on a smaller scale by creating areas of textured and non-textured glass across the substrate in a controlled manner. This may be done by controlling the deposition of the soot by masking the substrate during the soot deposition. This may take the form of a mask attached to the substrate that is later removed or a mask that is placed upon the substrate or in between the burner and the substrate. Alternatively, the soot may be removed in a pattern after deposition. The physical removal of particles may be partial or complete. Either partial removal or local displacement of particles without removal will provide a visible pattern but without creating completely non-textured regions. The removal of the deposited soot can be done by chemical means such as etching or mechanical means such as abrasion or a combination or chemical and mechanical means such as grinding followed by etching.

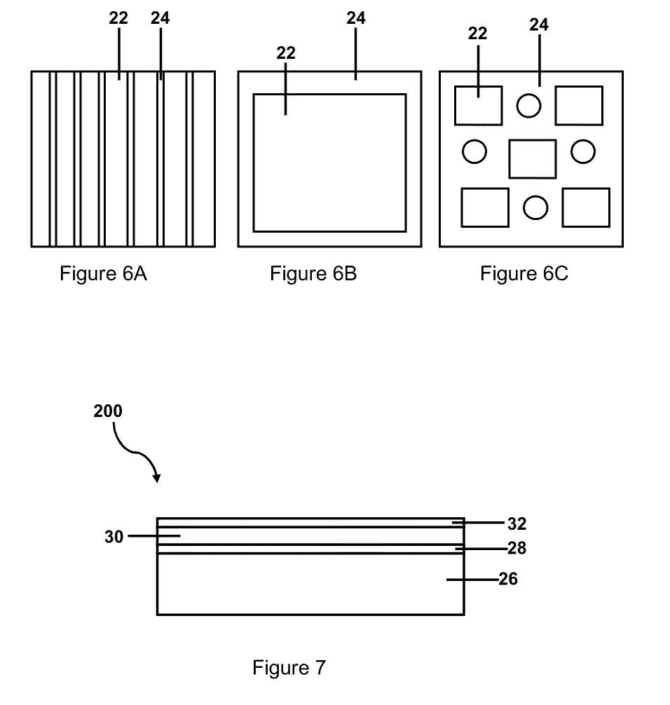

FIGS. 6A-6C are illustrations of exemplary light scattering articles having patterned soot. The illustrations are examples of some embodiments of light scattering articles comprising patterned soot. The patterns can be regular patterns or alternating patterns as shown in FIG. 6A where the textured areas comprising soot 22 alternates with the non-textured areas 24. The patterns can be irregular patterns or alternating patterns as shown in FIG. 6C where the textured areas comprising soot 22 alternates with the non-textured areas 24. In another embodiment, as shown in FIG. 6B, a specified area of non-textured areas 24 with textured areas comprising soot 22 around the edge or perimeter of the substrate. The textured areas 22 and the non-textured areas 24 shown in FIGS. 6A-6C in some embodiments can be switched such that the textured areas comprising soot 22 and the non-textured areas 24 are switched. The textured areas comprising soot and the non-textured areas can be of any shape or size.

FIG. 7 is an illustration of features 200 of an exemplary photovoltaic device using a light scattering substrate or article 26 according to the invention or made according to the methods of the invention. One embodiment is a photovoltaic device comprising the light scattering inorganic substrate made according to the methods disclosed herein. The photovoltaic device, according to one embodiment further comprises a conductive material 28 adjacent to the substrate, and an active photovoltaic medium 30 adjacent to the conductive material.

The active photovoltaic medium, according to one embodiment, is in physical contact with the conductive material. The conductive material, according to one embodiment is a transparent conductive film, for example, a transparent conductive oxide (TCO). The transparent conductive film can comprise a textured surface.

The photovoltaic device, in one embodiment, further comprises a counter electrode 32 in physical contact with the active photovoltaic medium 30 and located on an opposite surface of the active photovoltaic medium as the conductive material.

In one embodiment, a light scattering inorganic substrate is created having a textured surface that is suitable for subsequent deposition of a TCO and thin film silicon photovoltaic device structure.

This process is applicable to a broad range of soot particles and substrates. The sintering conditions need to be optimized for each material system and the type of surface structure that is desired.

The method, according to some embodiments, comprises depositing a silica-based soot onto a glass substrate followed by sintering at a sufficiently high temperature and sufficiently long time to at least partially sinter the soot without distorting the underlying substrate. Depending on the deposition conditions, it may be possible to simultaneously deposit and sinter the glass using heat from the burner and thereby eliminate the need for a separate sintering process.

FIG. 1 illustrates a potential large scale version of this process where a linear burner 16 is used to produce soot particles 14 and cover a wide substrate 10 with deposited soot particles 12 and the substrate moves under the burner at some velocity in a direction 20. Gas lines 18 may include the glass containing precursors (liquid or vapor delivery), oxygen for combustion and glass oxide reaction, methane or hydrogen for an ignition flame, and inert gases such as nitrogen or argon for burner flame optimization.

The process may use a wide variety of dopants in the silica to control the sintering temperature including boron, germanium, phosphorous, and fluorine. The glass substrate may be a low temperature glass such as soda-lime, a high temperature glass such as aluminosilicate, an intermediate temperature glass such as being developed for thin-film cadmium telluride (CdTe) or copper indium gallium diselenide (CIGS) PV cells, or even quartz or fused silica. Sintering temperatures may vary over a wide range from −500° C. to −1600° C. depending on the soot composition and the substrate glass. CTE matching of the sintered soot to the substrate glass may be required depending on the thickness of the soot.

A combination of volumetric and surface scattering provides degrees of freedom for optimization of both scattering and surface texture. For example, in volumetric scattering embodiments, air bubbles may be trapped in the sintered particles, the softened substrate, at their interface, or a combination thereof thus producing a volumetric scattering effect.

The process is applicable to different glass substrates by changing the soot composition and thereby the required sintering temperature.

A range of scattering properties may be produced by varying the sizes of the sintered microstructure by control of deposition and/or sintering parameters. These include soot particle agglomeration by residence time and mass of material in the flame. These can be controlled by flow rates of burner gasses and mass flow rates, stoiciometry, and burner to substrate distance. Multiple burners may be run in series with different conditions to deposit multiple particle size distributions. There is no need for additional chemical processing. It is expected that the process can be scaled to large sizes. For example, inorganic substrates up to 1.5 m² or larger could be coated with soot particles.

### EXAMPLES

The above described method was demonstrated using B-doped SiO₂ deposited by a pyrogenic process with a burner as is used for depositing soot for the fabrication of optical fibers by outside-vapor deposition (OVD). The required sintering temperature is a sensitive function of the B dopant concentration in the glass. BCl₃ was used as the precursor gas for B₂O₃. Two B₂O₃ concentrations were investigated. Based upon microprobe measurements, the maximum B₂O₃ concentration on the samples was 10.5 weight percent (wt %) and 22 wt %. To sinter the samples, the following furnace schedule was used:

1. The furnace was ramped to the target temperature at 10° C./hour.

2. The furnace was held at the target temperature for 1 hour.

3. The furnace was ramped down at a rate of 10° C./hour (actually decrease is slower since the furnace does not cool this quickly)

For the 10.5 wt % samples, nearly complete sintering was achieved at temperatures above 950° C. on quartz substrates. For the 22 wt % samples, nearly complete sintering was achieved at temperatures above 875° C. on both quartz and EagleXG™ substrates.

Due to composition variations across the samples, it is difficult to obtain a uniform area of sufficient size to characterize properly. Nevertheless, scattering measurements were done on one of the samples fabricated on quartz with the 22 wt % B₂O₃ soot. A line scan of the cosine-corrected bidirectional transmittance function (ccBTDF) at 400 nm, 600 nm, 800 nm, and 1000 nm is shown in FIG. 2. This shows an increase in scattering out to an angle of about 30 degrees.

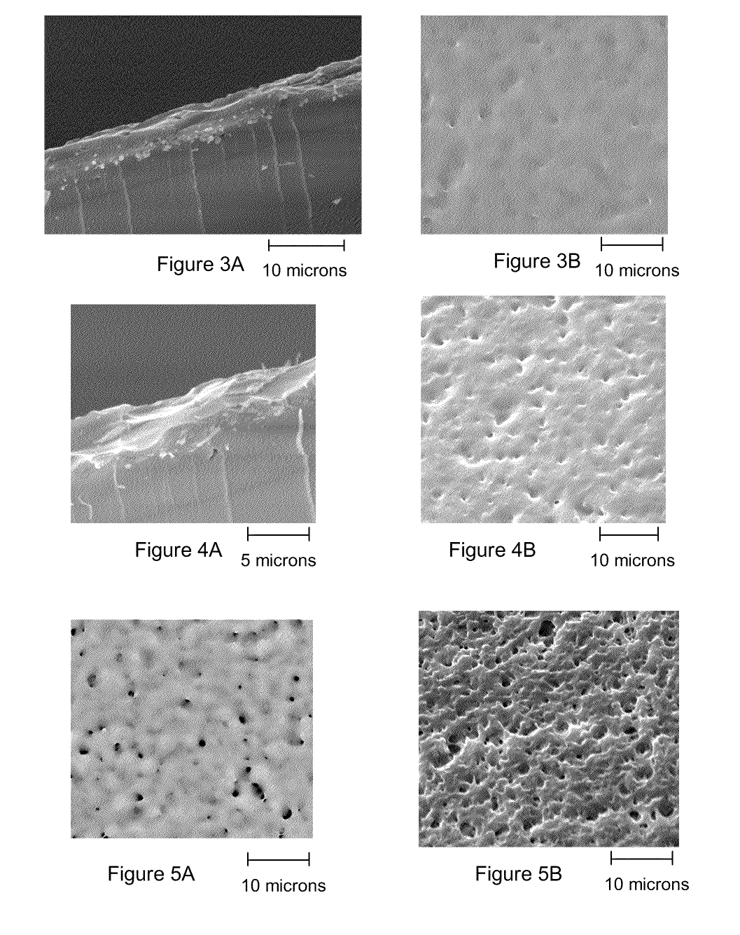

A sample with 22 wt % B₂O₃ soot on quartz sintered at 885° C. was evaluated with an SEM. The analysis indicates a range of sintering behavior that correlates with the varying B₂O₃ concentration across the sample. FIGS. 3A and 4A show cross sectional views of the sample in different regions. FIGS. 3B and 4B show top down views of the sample in different regions. The region in FIGS. 3A and 3B has a higher B₂O₃ concentration and therefore a denser and smoother structure than the region in FIGS. 4A and 4B. FIGS. 5A and 5B show top views of regions with varying levels of consolidation. In the least sintered case, FIG. 5B, the structure is highly porous and probably not suitable for an application that requires the deposition of a thin film. Further optimization of the sintering conditions and soot composition is required to fully understand the range of scattering available from this technique.

As mentioned above, there are many potential variables available to optimize this process. The starting substrate determines the maximum sintering temperature and thereby the allowable composition of soot. It appears from the SEM images that this process provides scattering primarily by surface texture although the voids may play some role in glass that is less completely consolidated. The soot thickness, soot particle size, substrate composition, and sintering conditions likely all play a role in determining the textures that are created. The glass texture may interact with a texture from the TCO deposited on the substrate. In that case, the combination of substrate texture and TCO texture must be optimized.

It will be apparent to those skilled in the art that various modifications and variations can be made to the present invention without departing from the spirit or scope of the invention. Thus, it is intended that the present invention cover the modifications and variations of this invention provided they come within the scope of the appended claims and their equivalents.

What is claimed is:

1. A method for making a light scattering inorganic substrate, the method comprising:
providing an inorganic substrate comprising at least one surface;
applying soot particles pyrogenically to the at least one surface of the inorganic substrate to form a coated substrate; and
heating the coated substrate to form the light scattering inorganic substrate.

2. The method according to claim 1, wherein the heating the coated substrate occurs as the soot particles are applied to the inorganic substrate.

3. The method according to claim 1, wherein the heating the coated substrate occurs subsequent to the applying the soot particles to the inorganic substrate.

4. The method according to claim 1, wherein the heating comprises softening the inorganic substrate.

5. The method according to claim 1, wherein the heating comprises softening the inorganic substrate and softening the soot particles.

6. The method according to claim 1, wherein the heating comprises sintering the soot particles.

7. The method according to claim 6, wherein the sintering the soot particles occurs as the soot particles are applied to the inorganic substrate.

8. The method according to claim 6, wherein the sintering the soot particles occurs subsequent to the applying the soot particles to the inorganic substrate.

9. The method according to claim 1, wherein the inorganic substrate comprises a material selected from a glass, a ceramic, a glass ceramic, sapphire, silicon carbide, a semiconductor, and combinations thereof.

10. The method according to claim 1, wherein the soot particles comprise a material selected from a glass, a ceramic, a glass ceramic, sapphire, silicon carbide, a semiconductor, metal oxides, and combinations thereof.

11. The method according to claim 1, wherein the soot particles comprise a material selected from silica, boron doped silica, germanium doped silica, phosphorous doped silica, and fluorine doped silica, and combinations thereof.

12. The method according to claim 1, wherein the applying the soot particles comprises depositing the soot particles using a linear burner, a point source burner, a series of linear burners, a series of point source burners, an array of linear burners, or an array of point source burners.

13. The method according to claim 1, wherein the applying the soot particles comprises patterning the soot particles.

14. The method according to claim 1, further comprising patterning the soot particles after the applying.

15. A photovoltaic device comprising the light scattering inorganic substrate made according to the method of claim 1.

16. The device according to claim 15, further comprising
a conductive material adjacent to the substrate; and
an active photovoltaic medium adjacent to the conductive material.

17. The device according to claim 16, wherein the conductive material is a transparent conductive film.

18. The device according to claim 17, wherein the transparent conductive film comprises a textured surface.

19. The device according to claim 16, wherein the active photovoltaic medium is in physical contact with the transparent conductive film.

20. The device according to claim 16, further comprising a counter electrode in physical contact with the active photovoltaic medium and located on an opposite surface of the active photovoltaic medium as the conductive material.

21. A light scattering article comprising a glass substrate having a surface comprising a pattern of textured areas comprising glass soot and a pattern of non-textured areas.
